(19) United States
(12) Patent Application Publication
(10) Pub. No.: US 2011/0013787 A1
(43) Pub. Date: Jan. 20, 2011

(54) MEMS MICROPHONE PACKAGE AND MEHTOD FOR MAKING SAME

(75) Inventor: JEN-TSORNG CHANG, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/609,130

(22) Filed: Oct. 30, 2009

(30) Foreign Application Priority Data
Jul. 16, 2009 (CN) 200910304424.6

(51) Int. Cl. H04R 11/04; H01L 21/50

(52) U.S. Cl. 381/174; 438/51; 257/E21.499

(57) ABSTRACT

An exemplary micro-electro-mechanical systems (MEMS) microphone package includes a first substrate, a second substrate opposite to the first substrate, and a microphone chip disposed on the second substrate. First through holes are defined in the first substrate. Conductive material is disposed in each first through hole. A through hole is defined in the second substrate. Contact pads are disposed on the second substrate. Each contact pad connects the corresponding electrically conductive material in each first through hole. The microphone chip is surrounded by the contact pads. When sound waves transmit through the through hole in the second substrate to the microphone chip, the microphone chip converts sound into an electrical signal.

### BACKGROUND

1. Technical Field

The present disclosure relates to microphone packages and, particularly, to micro-electrical-mechanical systems (MEMS) microphone packages, and methods for making the MEMS microphone packages.

2. Description of Related Art

A condenser microphone used in communication products usually has an electret formed on a back plate. Such condenser microphones are economical, but may not be very trendy as far as miniaturization. Thus, for extreme miniaturization of a microphone, an electrical capacity structure is realized on a silicon wafer in a die shape using a semiconductor-manufacturing technology and a MEMS technology. This electrical capacity structure is referred to as a silicon condenser microphone chip or a MEMS microphone chip. Such MEMS microphone chips must be packaged for protection against exterior interference and electrically connected with external circuit.

A typical MEMS microphone package is achieved in a manner where a microphone chip is disposed on a silicon substrate, and a housing accommodates the microphone chip. Then the housing is fixed to the substrate with an encapsulation adhesive. However, such encapsulation adhesive may cause the heat produced by the microphone chip difficult to dissipate outside.

Therefore, a MEMS microphone package and a method for making the MEMS microphone package which can overcome the above mentioned problems are desired.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the views.

FIG. 1 is a schematic, cross-sectional view of a MEMS microphone package according to an exemplary embodiment of the present disclosure.

FIG. 2 is a schematic, cross-sectional view of a first substrate.

FIG. 3 is a schematic, cross-sectional view showing a plurality of first through holes formed in the first substrate.

FIG. 4 is a schematic, cross-sectional view showing electrically conductive material filled in each first through hole.

FIG. 5 is a schematic, cross-sectional view showing a plurality of bulk solders formed on the first surface of the first substrate, and on the electrically conductive material.

FIG. 6 is a schematic, cross-sectional view showing a plurality of second through holes formed in the first substrate.

FIG. 7 is a schematic, cross-sectional view showing a second substrate provided opposite to the first substrate.

FIG. 8 is a schematic, cross-sectional view showing an isolation layer formed on the second substrate.

FIG. 9 is a schematic, cross-sectional view showing a back plate formed on the isolation layer.

FIG. 10 is a schematic, cross-sectional view showing a vibrating member formed on the second substrate.

FIG. 11 is a schematic, cross-sectional view showing two electrodes formed on the back plate and a diaphragm of the vibrating member, respectively.

FIG. 12 is a schematic, cross-sectional view showing a detection circuit formed on the second substrate.

FIG. 13 is a schematic, cross-sectional view showing a through hole formed in the second substrate.

FIG. 14 is a schematic, cross-sectional view showing a through hole formed in the isolation layer and the back plate.

FIG. 15 is a schematic, cross-sectional view showing a plurality of contact pads formed on the second substrate, and each contact pad corresponding to electrically conductive material in each first through hole.

### DETAILED DESCRIPTION

Various embodiments will now be described in detail below with reference to the drawings.

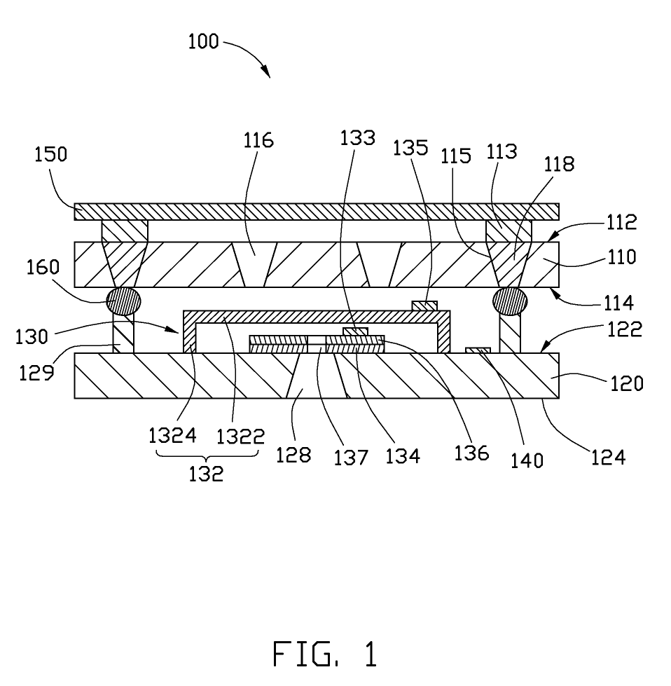

Referring to FIG. 1, an exemplary MEMS microphone package 100 includes a first substrate 110, a second substrate 120 opposite to the first substrate 110, a microphone chip 130 disposed on the second substrate 120, and a detection circuit 140 electrically connected with the microphone chip 130.

The first substrate 110 includes a first surface 112 and a second surface 114 at the opposite sides thereof. A plurality of first through holes 115 and a plurality of second through holes 116 are defined in the first substrate 110. The first through holes 115 are defined along the peripheries of the first substrate 110 and the second through holes 116 are defined in a central area of the first substrate 110 between the first through holes 115. The second through holes 116 are for venting sound waves outside. In the present embodiment, the number of the first through holes 115 is two, and the number of the second through holes 116 is also two. In the present embodiment, each first through hole 115 tapers from the first surface 112 to the second surface 114 of the first substrate 110. In the present embodiment, each second through hole 116 also tapers from the first surface 112 to the second surface 114 of the first substrate 110. It can be understood that in alternative embodiments, each first through hole 115 or each second through hole 116 can be circular, elliptical, square, or regular hexagonal in cross-section.

Electrically conductive material 118 is disposed in each first through hole 115. Each first through hole 115 is filled with the electrically conductive material 118. A plurality of bulk solders 113 are disposed on the first surface 112 of the first substrate 110. Each bulk solder 113 is disposed on the corresponding electrically conductive material 118 in each first through hole 115. In the present embodiment, the bulk solders 113 are attached to a printed circuit board 150 by a solder reflow process. It can be understood that in alternative embodiments, the bulk solders 113 can be exposed.

The second substrate 120 includes a first surface 122 and a second surface 124 at the opposite sides thereof. The first surface 122 of the second substrate 120 is opposite to the second surface 114 of the first substrate 110. A plurality of contact pads 129 are disposed on the first surface 122 of the second substrate 120. The contact pads 129 surround the microphone chip 130. Each contact pad 129 is disposed spatially corresponding to the electrically conductive material 118 in the respective first through hole 115. A through hole 128 is defined in the second substrate 120. The through hole 128 is for allowing sound waves to reach the microphone chip 130. In the present embodiment, the through hole 128 tapers from the second surface 124 to the first surface 122 of the second substrate 120.

The detection circuit 140 is disposed on the first surface 122 of the second substrate 120. The detection circuit 140 is for detecting a voltage change signal from the microchip 130. In the present embodiment, the detection circuit 140 is a complementary metal oxide semiconductor (CMOS) chip.

The microphone chip 130 is disposed on the first surface 122 of the second substrate 120. In the present embodiment, the microphone chip 130 is a condenser microphone chip. The microphone chip 130 includes a vibrating member 132, an isolation layer 134, a back plate 136, and two electrodes 133, 135.

The isolation layer 134 is disposed on the first surface 122 of second substrate 120. The back plate 136 is disposed on the isolation layer 134.

The vibrating member 132 includes a pressure-sensitive diaphragm 1322 and a supporting unit 1324. The diaphragm 1322 is substantially parallel with the back plate 136. The diaphragm 1322 is capable of deforming under an external pressure, for example, a pressure caused by an acoustic wave. The length of the diaphragm 1322 in a longitudinal direction thereof is larger than that of the isolation layer 134 or the back plate 136. In the present embodiment, the material of the diaphragm 1322 is polysilicon. The supporting unit 1324 extends from opposite ends of the diaphragm 1322 respectively to the first surface 122 of the second substrate 120. The electrode 133 is disposed on the back plate 136. The electrode 135 is disposed on the diaphragm 1322. A through hole 137 is defined in the isolation layer 134 and the back plate 136. The through hole 137 communicates with the through hole 128 of the second substrate 120.

The microphone chip 130 faces the second through holes 116 of the first substrate 110. Electrically conductive material 118 in each first through hole 115 of the first substrate 110 connects the corresponding contact pad 129 on the second substrate 120 via a solder ball 160.

In operation, when sound is transmitted through the through hole 128 and the through hole 137, the diaphragm 1322 deforms under the acoustic wave. Thus, the distance between the diaphragm 1322 and the back plate 136 changes, and the capacity between the diaphragm 1322 and the back plate 136 changes accordingly. The variable capacity causes the change of voltage because the quantity of electricity (Q) remains the same. The voltage change signal is transferred to the detection circuit 140 via the electrodes 133, 135. The voltage change is detected by the detection circuit 140. The magnitude of the voltage change represents the sound intensity, and the frequency of the voltage change represents the sound frequency.

It can be understood that the type of the microphone chip 130 is not limited to the present embodiment. In other embodiment, the microphone chip 130 can be an electret microphone or a piezoelectric microphone.

An exemplary method for making the microphone package 100 is described in detail as follows:

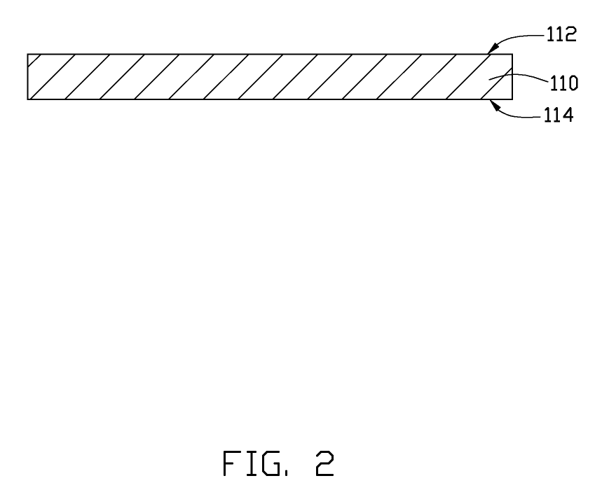

Referring to FIG. 2, the first substrate 110 is provided. The first substrate 110 includes a first surface 112 and a second surface 114 at the opposite sides thereof. The material of the first substrate 110 is selected from the group consisting of n-type silicon, p-type silicon, and intrinsic silicon.

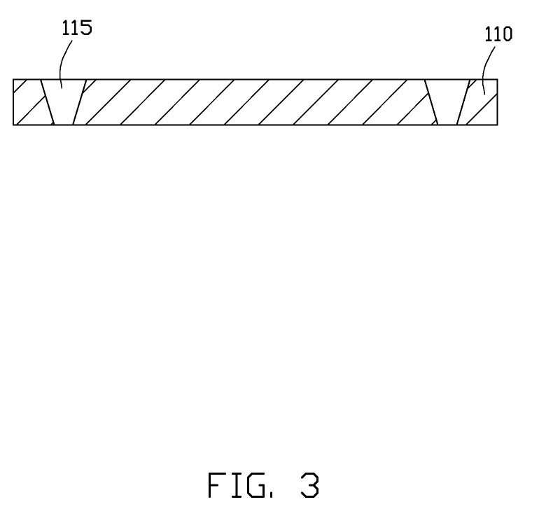

Referring to FIG. 3, a plurality of first through holes 115 are formed in the first substrate 110. The first through holes 115 are formed by an etching process. The etching process can be chosen from a wet etching or a dry etching. In the present embodiment, the etching process is a deep reactive ion etching (DRIE).

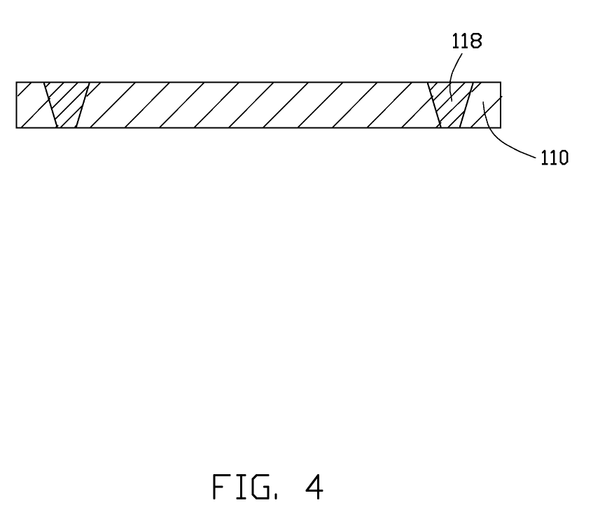

Referring to FIG. 4, electrically conductive material 118 is filled in each first through hole 115 by an electroplating or a printing process. The electrically conductive material 118 is selected from the group consisting of Au, Ag, Cu, Al, Ni and any alloy containing at least two elements thereof.

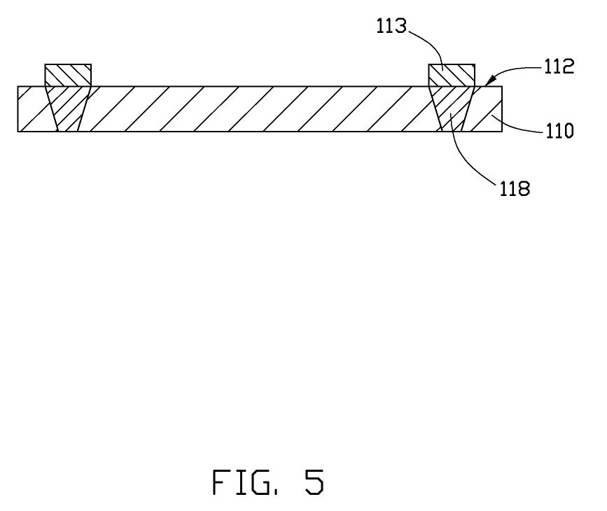

Referring to FIG. 5, a plurality of bulk solder 113 are formed on the first surface 112 of the first substrate 110 by an electroplating or a printing process. Each bulk solder 113 is formed on electrically conductive material 118 of each first through hole 115. The bulk solders 113 function as electrical terminals for external connection.

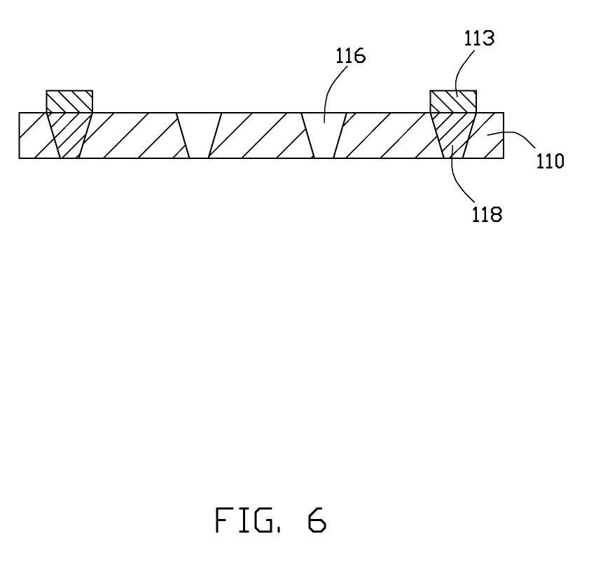

Referring to FIG. 6, a plurality of second through holes 115 are formed on the first substrate 110 by a drilling process. The drilling process can be, for example, laser drilling, mechanical drilling, or punching.

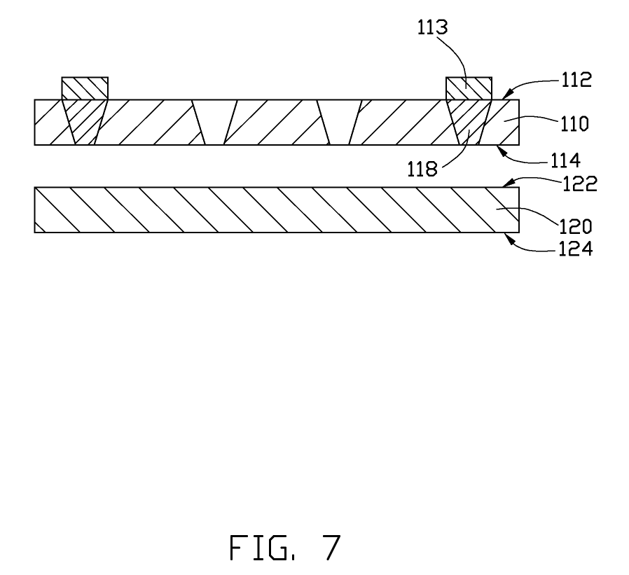

Referring to FIG. 7, the second substrate 120 is provided. The second substrate 120 includes a first surface 122 and a second surface 124 at the opposite sides thereof. The first surface 122 of the second substrate 120 is arranged opposite to the second surface 114 of the first substrate 110. The material of the second substrate 120 is selected from the group consisting of n-type silicon, p-type silicon, and intrinsic silicon.

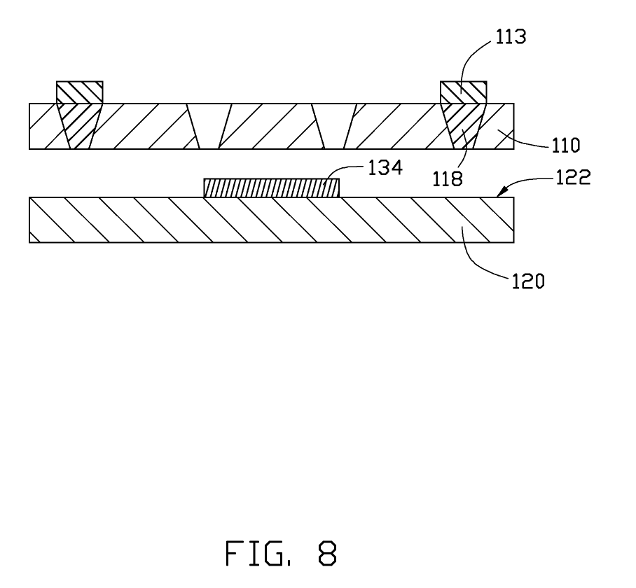

Referring to FIG. 8, the isolation layer 134 is formed on the first surface 122 of the second substrate 120. The isolation layer 134 can be formed by a chemical vapor deposition (CVD) or a physical vapor deposition (PVD) process. In the present embodiment, the material of the isolation layer 134 is silicon dioxide. In alternative embodiment, the material of the isolation layer 134 can be a composite of silicon dioxide and silicon nitride.

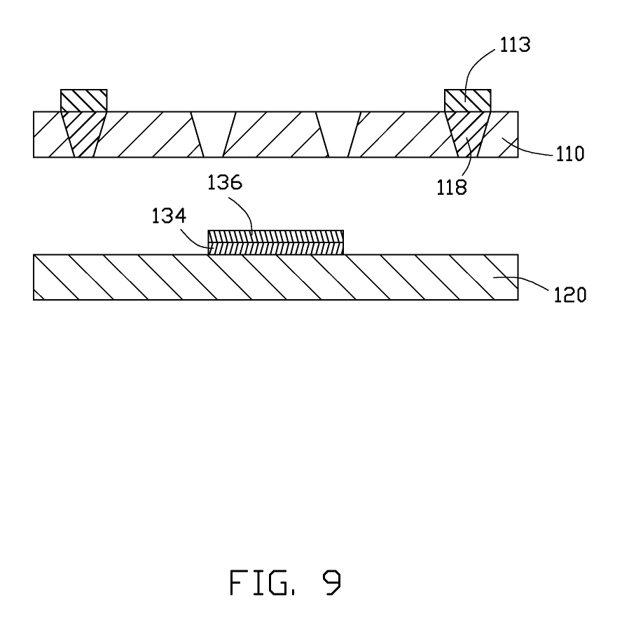

Referring to FIG. 9, the back plate 136 is formed on the isolation layer 134. The back plate 136 can also be formed by a CVD or a PVD process. In the present embodiment, the material of the back plate 136 is polysilicon.

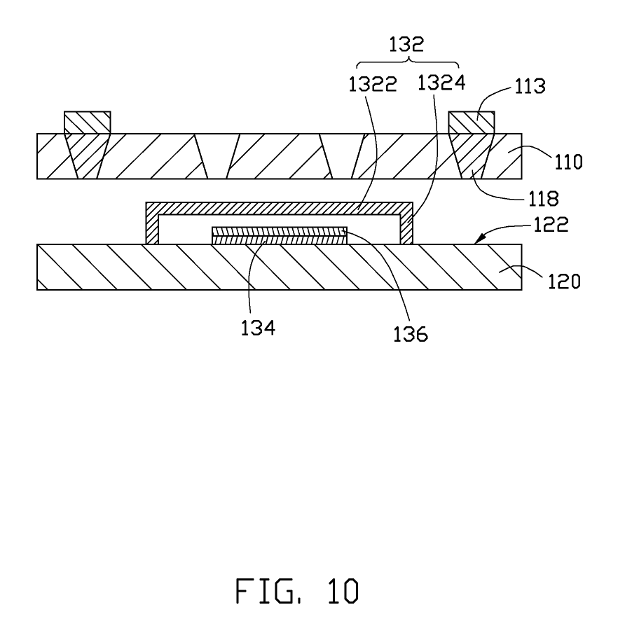

Referring to FIG. 10, the vibrating member 132 is formed on the first surface 122 of the second substrate 120. The supporting unit 1324 of the vibrating member 132 can attach the second substrate 120 via an adhesive or soldering.

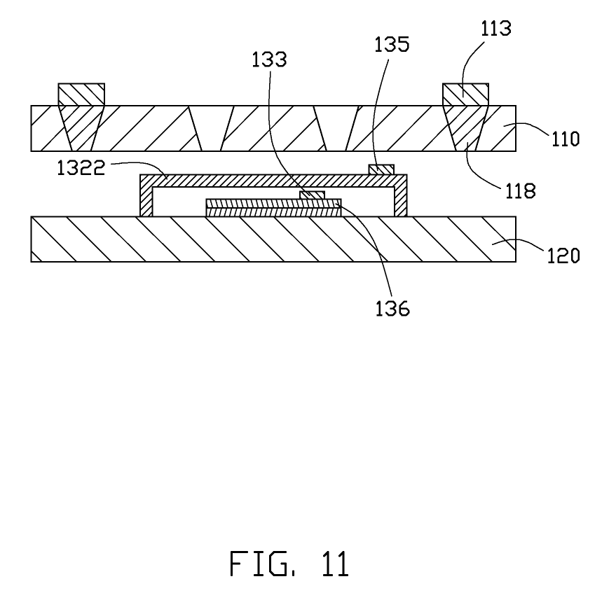

Referring to FIG. 11, the electrodes 133, 135 are formed on the back plate 136, and the diaphragm 1322, respectively. The electrodes 133, 135 can be formed by a CVD or a PVD process.

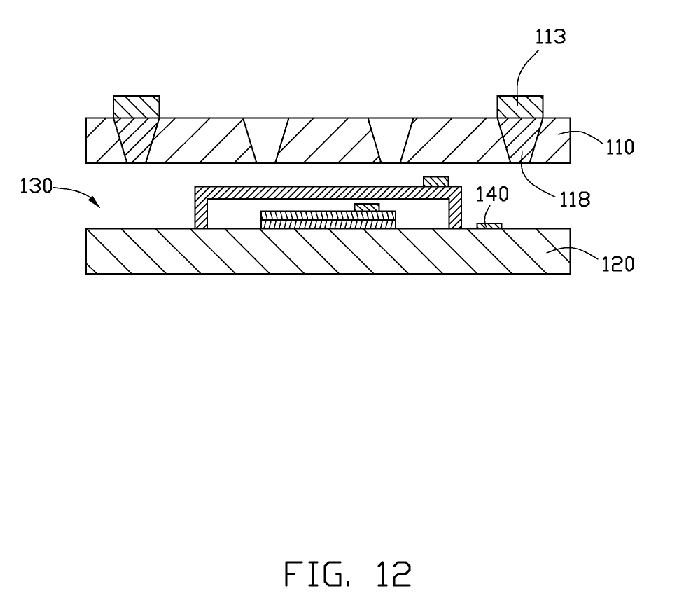

Referring to FIG. 12, the detecting circuit 140 is formed on the first surface 122 of the second substrate 120. The detecting circuit 140 is formed by a micro-electro-mechanical technique.

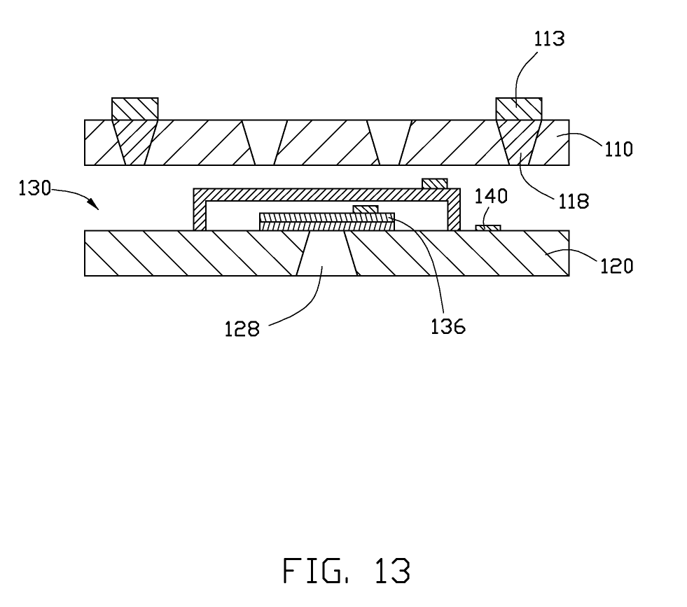

Referring to FIG. 13, the through hole 128 is formed by an etching process. In the present embodiment, the through hole 128 is formed by a DRIE process.

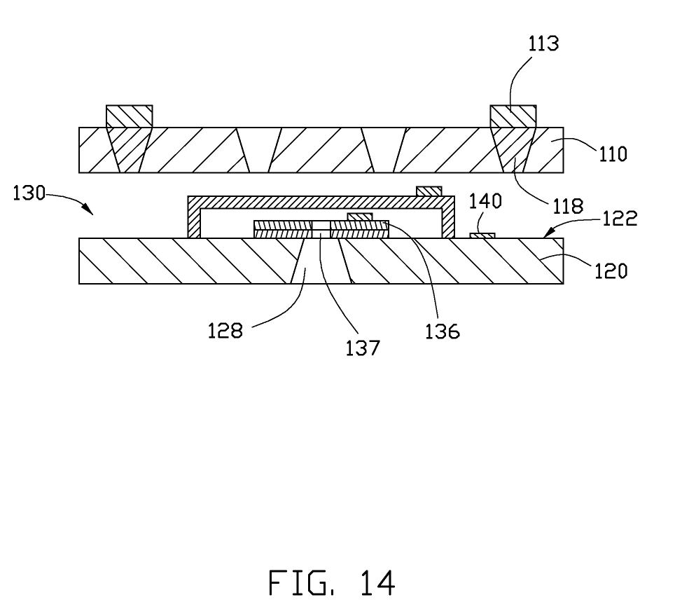

Referring to FIG. 14, the through hole 137 is formed by an etching process. In the present embodiment, the through hole 137 is formed by a DRIE process.

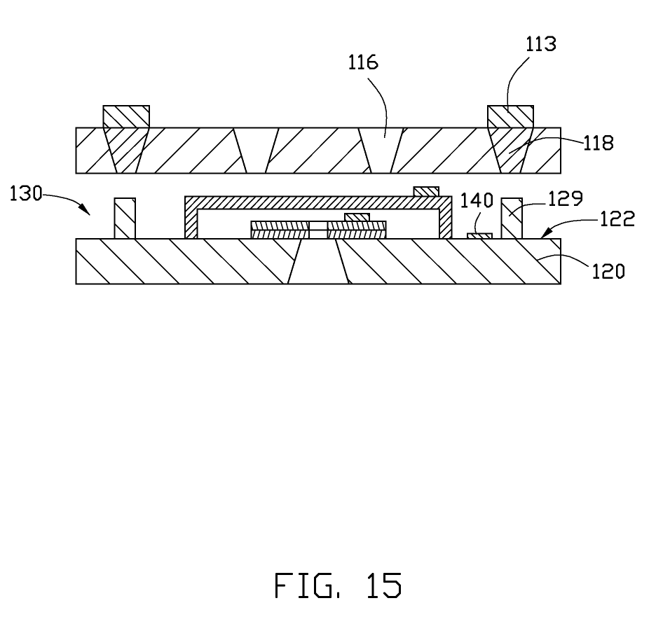

Referring to FIG. 15, a plurality of contact pads 129 are formed on the first surface 122 of the second substrate 120.

After the microphone chip 130 on the second substrate 120 is aligned with the second through holes 116, electrically conductive material 118 in each first through hole 115 is electrically connected with the corresponding contact pad 129 via a solder ball 160. Accordingly, the MEMS microphone package 100 as shown in FIG. 1 is obtained.

The MEMS microphone package 100 employs electrically conductive material 118 in each first through hole 115 electrically connecting the contact pads 129 on the second substrate 120 via solder balls 160. Therefore, the gap is defined between adjacent contact pads 129 or between adjacent solder balls 160, to further improve heat dissipation efficiency of the microphone chip 130.

While certain embodiments have been described and exemplified above, various other embodiments from the foregoing disclosure will be apparent to those skilled in the art. The present invention is not limited to the particular embodiments described and exemplified but is capable of considerable variation and modification without departure from the scope and spirit of the appended claims.

1. A MEMS (micro-electrical-mechanical systems) microphone package comprising:
a first substrate having a plurality of first through holes defined therein, and an electrically conductive material disposed in each first through hole;
a second substrate opposite to the first substrate, the second substrate having a through hole defined therein, a plurality of contact pads disposed on the second substrate, each contact pad electrically connected with the corresponding electrically conductive material; and
a microphone chip disposed on the second substrate, the microphone chip surrounded by the contact pads.

2. The MEMS microphone package of claim 1, wherein the first substrate further comprises a plurality of second through holes defined therein, the microphone chip faces the second through holes, and the second through holes are configured for venting sound outside.

3. The MEMS microphone package of claim 1, wherein the first through holes are defined in the periphery of the first substrate.

4. The MEMS microphone package of claim 1, wherein the MEMS microphone package further comprises a plurality of bulk solders, and each bulk solder is disposed on the electrically conductive material of the respective first through hole.

5. The MEMS microphone package of claim 1, wherein the microphone chip comprises a diaphragm, an isolation layer, and a back plate, the isolation layer is disposed on the substrate, the back plate is disposed on the isolation layer, the diaphragm is above and substantially parallel with the back plate, a through hole is defined in the isolation layer and the back plate, and the through hole communicates with the through hole in the second substrate.

6. A MEMS microphone package comprising:
a first substrate having a plurality of first through holes defined in the periphery thereof, and an electrically conductive material disposed in each first through hole;
a second substrate opposite to the first substrate, a through hole defined in the second substrate, a plurality of contact pads disposed on the second substrate, a solder ball electrically connected between each contact pad and the corresponding electrically conductive material; and
a microphone chip disposed on the second substrate, the microphone chip surrounded by the contact pads.

7. A method for making a MEMS microphone package, the method comprising:
forming a plurality of first through holes in a first substrate;
filling each first through hole with an electrically conductive material;
providing a second substrate, the second substrate opposite to the first substrate;
forming a microphone chip on a surface of the second substrate, the microphone chip facing the first substrate;
forming a through hole in the second substrate, the microphone chip covering the through hole in the second substrate;
forming a plurality of contact pads on the surface of the second substrate, the contact pads surrounding the microphone chip; and
electrically connecting the electrically conductive material in the first through holes with the corresponding contact pads.

8. The method of claim 7, wherein the conductive material in each first through hole connects the corresponding contact pad via a solder ball.

9. The method of claim 7, further comprising forming a plurality of second through holes in the first substrate, for venting sound outside.

10. The method of claim 7, wherein forming the microphone chip comprising:
forming an isolation layer on the surface of the second substrate;
forming a back plate on the isolation layer;
forming a through hole in the back plate and the isolation layer; and
forming a vibrating member on the surface of the second substrate, the vibrating member comprising a diaphragm and a supporting unit extends from opposite ends of the diaphragm respectively to the surface of the second substrate.

11. The method of claim 10, further comprising forming two electrodes on the diaphragm and the back plate respectively.

12. The method of claim 7, wherein the first through holes is formed by a deep reactive ion etching (DRIE) process.
